(19) United States
(12) Patent Application Publication
(10) Pub. No.: US 2018/0157428 A1
(43) Pub. Date: Jun. 7, 2018

(54) DATA PROTECTION OF FLASH STORAGE DEVICES DURING POWER LOSS

(71) Applicant: Alibaba Group Holding Limited, George Town (KY)

(72) Inventor: Shu Li, Bothell, WA (US)

(21) Appl. No.: 15/366,311

(22) Filed: Dec. 1, 2016

(51) Int. Cl. G06F 3/06; G06F 11/10; G11C 29/52

(52) U.S. Cl. CPC G06F 3/0619; G06F 3/0688; G06F 3/0655; G11C 29/52; G06F 3/0625; G06F 11/108; G06F 11/1072; G06F 3/0689

(57) ABSTRACT

Data writing to a plurality of pages included in a solid state drive (SSD) is initiated. A power loss is detected while there is at least one page amongst the plurality of pages that is at least partially unwritten. Parity protection is provided for the plurality of pages including by recording parity information based at least in part on data that is written to the plurality of pages and recording metadata associated with a last valid page.

### BACKGROUND OF THE INVENTION

When a storage system, such as a solid state drive (SSD), loses power unexpectedly, some host data may be lost. To prevent this, many SSD systems have backup power sources (e.g., batteries) which the SSD system uses to perform emergency shutdown procedures to prevent host data from being lost. However, not all corner cases and/or environments are covered by the existing techniques and new techniques which provide more comprehensive protection against data loss, including in such corner cases and/or environments, would be desirable. Furthermore, it would be desirable if such new techniques were efficient and/or required relatively short time to execute so that a smaller backup power source could be used or provisioned for the SSD system.

### BRIEF DESCRIPTION OF THE DRAWINGS

Various embodiments of the invention are disclosed in the following detailed description and the accompanying drawings.

FIG. 1 is a flowchart illustrating an embodiment of a process to provide data protection for a solid state drive (SSD).

FIG. 2 is a diagram illustrating an embodiment of an SSD system where the last valid page written is a complete page.

FIG. 3 is a flowchart illustrating an embodiment of a process to generate metadata and parity information.

FIG. 4 is a diagram illustrating an embodiment of an SSD system where the last valid page written is a partial page.

FIG. 5 is a diagram illustrating an embodiment of metadata which includes information associated with a partial page.

FIG. 6 is a flowchart illustrating an embodiment of a process to generate metadata and parity information for a partial page.

FIG. 7 is a diagram illustrating an embodiment of random sequences written to unwritten pages in a partial RAID group after power is restored.

FIG. 8 is a flowchart illustrating an embodiment of a re-initialization process after power is restored.

FIG. 9 is a flowchart illustrating an embodiment of a process to write a neutral data pattern.

FIG. 10 is a diagram illustrating an embodiment of metadata associated with a partial RAID group before and after being updated once power is restored.

FIG. 11 is a flowchart illustrating an embodiment of a process to modify metadata associated with a partial RAID group so that it resembles metadata for a complete RAID group once power is restored.

### DETAILED DESCRIPTION

The invention can be implemented in numerous ways, including as a process; an apparatus; a system; a composition of matter; a computer program product embodied on a computer readable storage medium; and/or a processor, such as a processor configured to execute instructions stored on and/or provided by a memory coupled to the processor. In this specification, these implementations, or any other form that the invention may take, may be referred to as techniques. In general, the order of the steps of disclosed processes may be altered within the scope of the invention. Unless stated otherwise, a component such as a processor or a memory described as being configured to perform a task may be implemented as a general component that is temporarily configured to perform the task at a given time or a specific component that is manufactured to perform the task. As used herein, the term ‘processor’ refers to one or more devices, circuits, and/or processing cores configured to process data, such as computer program instructions.

A detailed description of one or more embodiments of the invention is provided below along with accompanying figures that illustrate the principles of the invention. The invention is described in connection with such embodiments, but the invention is not limited to any embodiment. The scope of the invention is limited only by the claims and the invention encompasses numerous alternatives, modifications and equivalents. Numerous specific details are set forth in the following description in order to provide a thorough understanding of the invention. These details are provided for the purpose of example and the invention may be practiced according to the claims without some or all of these specific details. For the purpose of clarity, technical material that is known in the technical fields related to the invention has not been described in detail so that the invention is not unnecessarily obscured.

Various embodiments of processes performed by a solid state drive (SSD) with RAID protection in response to an unexpected loss of power are described herein. First, some examples of processes which are performed before and/or once power is lost are described (e.g., at least some part of these processes are performed using a backup power source, such as a battery). Then, some examples of processes which are performed once power is restored are described. In various embodiments, these processes may be performed separately or in some combination with each other.

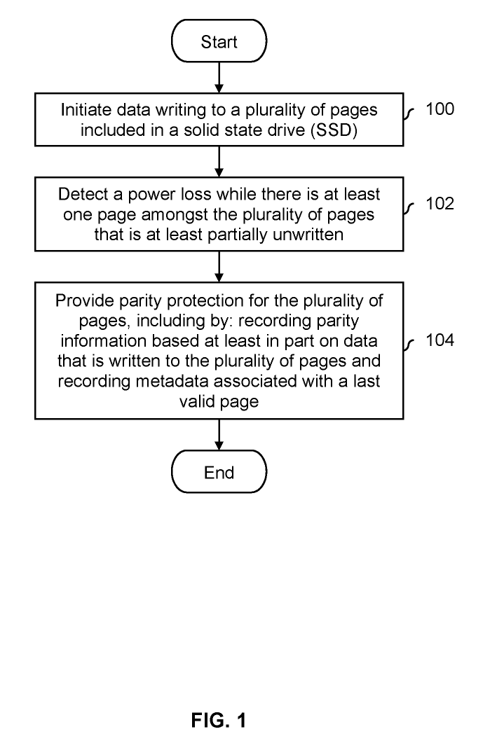

FIG. 1 is a flowchart illustrating an embodiment of a process to provide data protection for a solid state drive (SSD). In some embodiments, the process is performed by a NAND flash controller (e.g., which may be implemented on a processor, such as a general purpose processor, an application-specific integrated circuit (ASIC), or a field-programmable gate array (FPGA)).

At 100, data writing to a plurality of pages included in a solid state drive (SSD) is initiated. For example, the plurality of pages being written may be associated with the same redundant array of inexpensive/independent disks (RAID) group. If one of the N pages in the RAID group fails and cannot be read back, the other pages in the RAID group and some associated parity information may be used to regenerate the bad page using error correcting techniques.

At 102, a power loss is detected while there is at least one page amongst the plurality of pages that is at least partially unwritten. For example, some NAND flash controllers have a write buffer to temporarily store write data from a host before the write data is actually written to one or more of the plurality of pages. Typically, such write buffers are implemented using volatile storage (which loses its stored information if power is lost) because non-volatile storage is more expensive and/or the low latency of volatile storage. If the SSD system loses power while there is some write data in a volatile write buffer (i.e., that has not actually been written to the plurality of pages), then that is one example of the scenario described by step 102. A power loss may be detected using any appropriate technique and for brevity is not described herein.

Another example scenario which satisfies step 102 is if the SSD system is quiescent (e.g., no data is being sent from the host to the NAND flash controller and no data is in the NAND flash controller's write buffer waiting to be written to the plurality of pages in the NAND flash) but there are still unwritten pages in the RAID group. It is still desirable to provide parity protection (e.g., per step 104) in this scenario.

In some applications, the SSD system has some backup power source, such as a battery and/or capacitor, which the SSD system uses in the event power is lost. In some embodiments, step 104 is performed using a backup power source.

At 104, parity protection is provided for the plurality of pages, including by: recording parity information based at least in part on data that is written to the plurality of pages and recording metadata associated with a last valid page. As will be described in more detail below, the metadata associated with the last valid page may be recorded in a decentralized manner (e.g., in a header associated with the last valid page) and/or in a central location (e.g., in processor storage, such as DRAM attached to ARM core(s)).

In some embodiments, the parity information recorded at step 104 is associated with RAID protection. For example, after power is restored, if one of the pages in the RAID group cannot be read back, the parity information recorded at step 104 is available so that RAID recovery can be performed. In some previous SSD systems with RAID protection, if power was lost unexpectedly while the RAID group was incomplete, that RAID group would have no RAID protection. By generating and recording parity information (e.g., in response to a power loss while the RAID group is incomplete), RAID protection is provided. This permits any of the pages in that RAID group to be recovered using RAID, whereas previously no RAID recovery was possible if power was lost unexpectedly.

In some embodiments, the metadata recorded at step 104 is associated with flash translation layer (FTL) information which includes mappings between logical (block) addresses (e.g., which the host uses when issuing read or write instructions to the NAND flash controller) and physical (block) addresses (e.g., where the data is actually or physically stored in the NAND flash). For example, the logical to physical mapping information may be used to execute a read instruction issued by a host after power is restored: the read instruction from the host to the NAND flash controller includes the logical address, the NAND flash controller determines the physical address(es) which correspond to the logical address using the FTL information, and accesses the data stored in those physical address(es).

To ensure that the parity information and metadata which are recorded at step 104 are available once power is restored, in some embodiments, the parity information and metadata are stored in the plurality of pages (e.g., because the pages are in NAND flash which is non-volatile).

If needed (e.g., depending upon the embodiment or implementation), the NAND flash controller also writes any data in the NAND flash controller's write buffer to page(s) in the NAND flash. As described above, write buffers are often implemented using volatile storage, whereas NAND flash is non-volatile and is able to retain information stored thereon even if power is lost.

The following figure is an example SSD system which illustrates how the process of FIG. 1 may be performed.

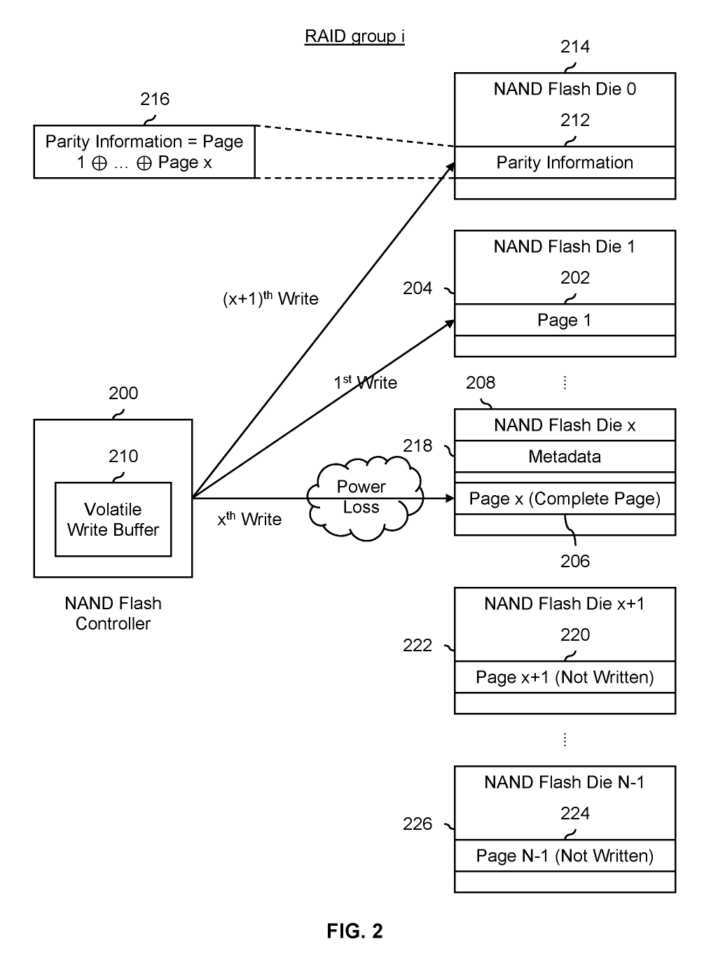

FIG. 2 is a diagram illustrating an embodiment of an SSD system where the last valid page written is a complete page. In the example shown, the NAND flash controller (200) receives write instructions from a host (not shown). The first write by the NAND flash controller is to page 202 (i.e., page 1) on die 204 (i.e., a NAND flash die 1). In this example, the NAND flash controller includes volatile write buffer (210) to which write data from the host is temporarily stored before that data is actually written to the appropriate page. As such, the write data for page 202 is temporarily stored in the volatile write buffer before being written to page 202.

The NAND flash controller continues writing to the pages (e.g., page 2, then page 3, and so on) in response to host write instructions (not shown) until the x^{th} write. In this example, a power loss occurs while the write data for the x^{th} write is still stored on volatile write buffer (210) and before the data is actually written to page 206 (i.e., page x) on die 208 (i.e., NAND flash die x). The NAND flash controller in this example acknowledges any write data from the host even before that data is actually written to the appropriate page and so the NAND flash controller has to make sure the write actually happens (e.g., so that the write data for the x^{th} write is stored on NAND flash, which is non-volatile, and can be read back later). As such, using a backup power source (not shown), NAND flash controller 200 performs the x^{th} write to page 206 (i.e., page x) on die 208 (i.e., NAND flash die x).

Still operating on backup power, the NAND flash controller generates parity information for the exemplary RAID group shown and stores it at page 212 on die 214 (i.e., NAND flash die 0). Callout 216 shows in more detail that the parity information is an (e.g., bit-wise) exclusive OR (XOR) of all of the valid data (i.e., the write data associated with page 1 through page x in the RAID group). Using an XOR is efficient because it is easy to implement in hardware and/or is fast. Since the parity information stored at page 212 is stored on non-volatile storage, RAID recovery can be performed if any one of the pages in this RAID group fails and cannot be read (e.g., using the parity information and the (x−1) good pages, the bad page is recovered). This is one example of the parity information recorded at step 104 in FIG. 1.

The NAND flash controller also uses backup power to generate and store metadata 218. In this example, metadata 218 includes the logical to physical mapping information associated with page 206 (i.e., the last valid page), including the logical (block) address which corresponds to the physical (block) address associated with page 206. For simplicity, in this example, one logical (block) address equals one physical (block) address. In this example, metadata 218 is stored in some pre-defined page or location on die 208 which is reserved for FTL information (e.g., the beginning or end of a given NAND flash die). For example, once the SSD system has power again, the NAND flash controller goes to the pages or locations which are reserved for FTL information and reads the information stored therein in order to know what logical (block) addresses correspond to what physical (block) addresses. Metadata 218 is one example of metadata which is recorded at step 104 in FIG. 1. Naturally, metadata and/or FTL information may be arranged or stored in any manner or location and this is merely one example.

In some embodiments, metadata and/or FTL information is stored in some out of bounds and/or over-provisioned part of the NAND flash die. For example, NAND flash manufacturers may include extra cells in each die because program and erase operations are hard on NAND flash cells and repeated programming and erasing eventually wears out at least some of the cells over time. These extra cells may be accessible to the NAND flash controller and the NAND flash controller may store metadata in this out of bounds and/or over-provisioned part of the NAND flash die. In some embodiments, metadata 218 is stored in out-of-bounds cells immediately before page 206 (e.g., so that metadata 218 is a header of sorts to page 206).

In some embodiments, metadata and/or FTL information is stored in multiple locations. For example, in addition to being stored as a “header” to a corresponding page, the NAND flash controller may keep FTL information in some centralized location. Storing metadata and/or FTL information in multiple locations may be good for redundancy and/or to improve access times.

If needed, any other metadata and/or FTL information is recorded on non-volatile storage. For example, if the NAND flash controller is configured to write all of the FTL information only after all of the write data for the exemplary RAID group has been received (e.g., as opposed to writing a page and then immediately recording the FLT information for that page), then the metadata and/or FTL information for page 1-page (x−1) is also stored by the NAND flash controller using backup power.

It is noted that page 220 (i.e., page (x+1)) on die 222 (i.e., NAND flash die (x+1)) through page 224 (i.e., page (N−1)) on die 226 (i.e., NAND flash die (N−1)) are not written, using backup power. They are left in an unwritten and/or erased state (e.g., at least when operating on backup power) to minimize the size of a battery that must be provisioned for emergency shutdown processing. As will be described in more detail below, in some embodiments, once power is restored, the NAND flash controller writes to those unwritten pages in order to prevent noise (e.g., in the form of additional, unintended charge being added to the pages shown).

The following figure more formally describes the process shown here as a flowchart.

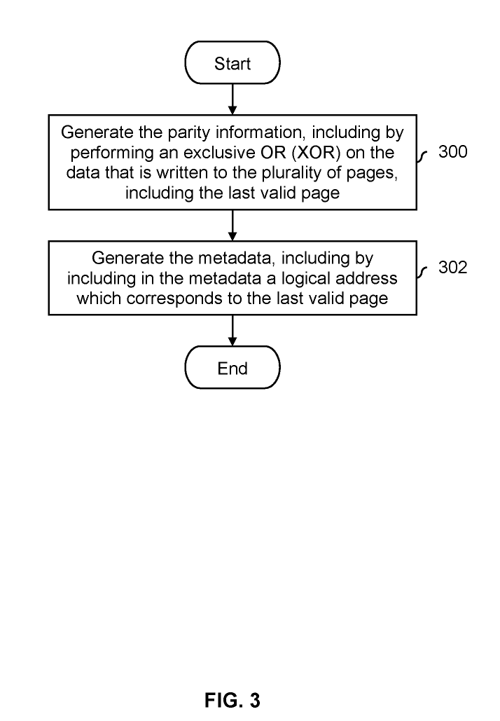

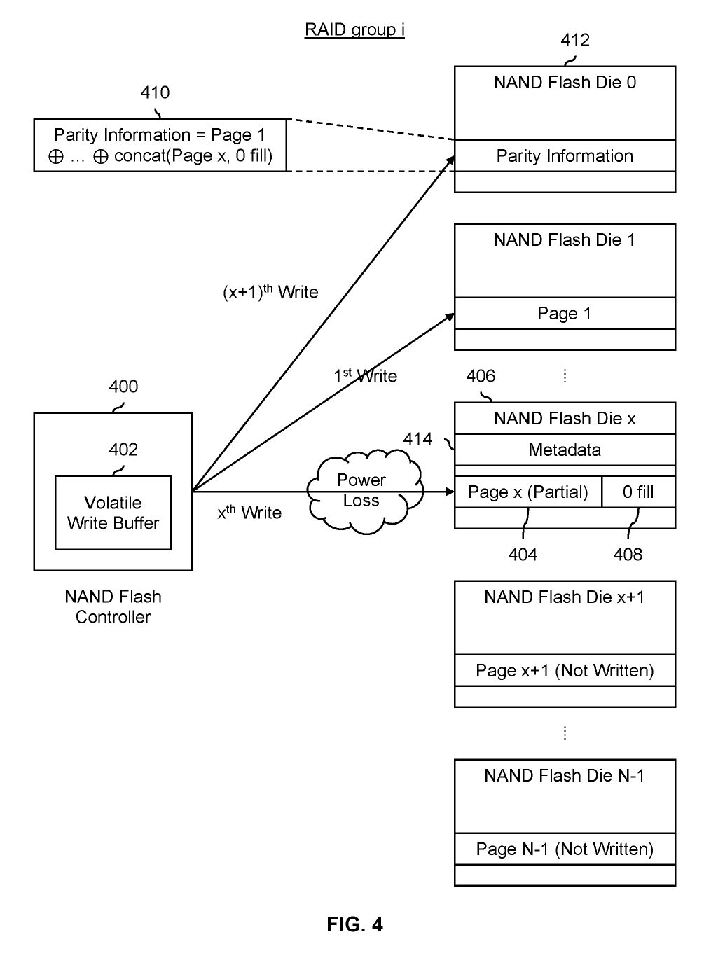

FIG. 3 is a flowchart illustrating an embodiment of a process to generate metadata and parity information. In some embodiments, the process of FIG. 3 is performed in combination with the process of FIG. 1 (e.g., the parity information and metadata recorded at step 104 in FIG. 1 is generated by the process of FIG. 3). In some embodiments, the process of FIG. 4 is performed by a NAND flash controller.

At 300, the parity information is generated, including by performing an exclusive OR (XOR) on the data that is written to the plurality of pages, including the last valid page. See, for example, callout 216 in FIG. 2 which says, “Parity Information=Page 1 ⊕ . . . ⊕ Page x” where page x is the last valid page written to the RAID group shown. In the example of FIG. 2, the parity information is stored on a die which only stores parity information (e.g., there is no host data stored on die 214) but naturally parity information may be organized and/or stored in any manner.

At 302, the metadata is generated, including by including in the metadata a logical address which corresponds to the last valid page. For example, metadata 218 in FIG. 2 includes a logical address which corresponds to the physical address of page x (206). As described above, a logical address which is included in metadata 218 may be obtained from a write instruction from the host.

In the example of FIG. 2, the last valid page (i.e., page 206) is a complete page. In some cases, the last valid page is a partial page and the following figure shows an example of this.

FIG. 4 is a diagram illustrating an embodiment of an SSD system where the last valid page written is a partial page. FIG. 4 is similar to FIG. 2, in that power is lost while write data associated with an x^{th} write is stored in volatile write buffer 402 and before that data is written to the NAND flash. As before, NAND flash controller 400 uses backup power to write the write data (404) in volatile write buffer 402 to page x on die 406 (i.e., NAND flash die x). However, the write data associated with the x^{th} write is a partial page and does not fill up an entire page. The remainder of the page is filled with one or more zeros (408), referred to herein as a zero fill.

To generate the parity information, the NAND flash controller uses backup power to XOR page 1 through page x. Since page x is a partial page, the zero fill is concatenated or appended to the end of partial page x. This is shown in callout 410. As before, the parity information is stored on die 412 (i.e., NAND flash die 0).

The NAND flash controller also uses backup power to generate and store metadata 414, which includes a logical (block) address associated with page x (or, more generally, the FTL information for the last valid page). When the last valid page is a partial page as shown in this example, the FTL information and/or metadata may include some flag or bit which indicates that page x is a partial page and the length of the valid portion. A more detailed example is described below.

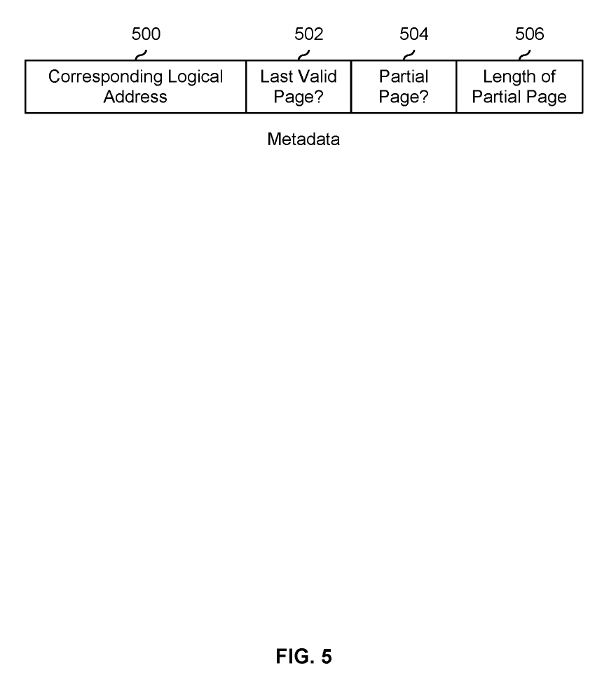

FIG. 5 is a diagram illustrating an embodiment of metadata which includes information associated with a partial page. In this example, the metadata includes three fields: a corresponding logical address (500), a last valid page bit (502) which indicates whether the corresponding page is the last valid page in a partial RAID group (e.g., where a partial RAID group is one in which not all N−1 pages in the RAID group have host data versus a complete RAID group where all N−1 pages in the RAID group have host data), a partial page bit (504) which indicates whether the corresponding page is a partial page (e.g., 1=partial page, 0=complete page), and a length field (506) which records the length of the partial page, if applicable.

In some embodiments, metadata 218 in FIG. 2 and metadata 414 in FIG. 4 are implemented as shown, but with different values for the various fields. For both metadata 218 in FIG. 2 and metadata 414 in FIG. 4, the last valid page bit is set to 1 because the corresponding page (i.e., page x) is the last valid page in a partial RAID group. The logical (block) addresses would be the two logical addresses corresponding to the respective pages. For the partial page bit, for the example of FIG. 2, that bit would indicate that the page is a complete page and the length field would be not applicable and/or set to some reserved or default value. In contrast, for the example of FIG. 4, the partial page bit would indicate that the corresponding page is a partial page and the length of the partial page would be recorded (e.g., so that where the host data ends and the zero fill begins is known).

Alternatively, the information shown in this example may be organized and/or stored in some other manner. For example, the NAND flash controller may only record “exceptions,” such as which RAID groups are partial RAID groups and associated information for those exceptional, partial RAID groups (e.g., the location of the last valid page for those partial RAID groups, if that last valid page is a partial page and, if so, how long that last valid page is, etc.). In other words, this figure is merely exemplary and is not intended to be limiting.

The following figure more formally describes the process shown here as a flowchart.

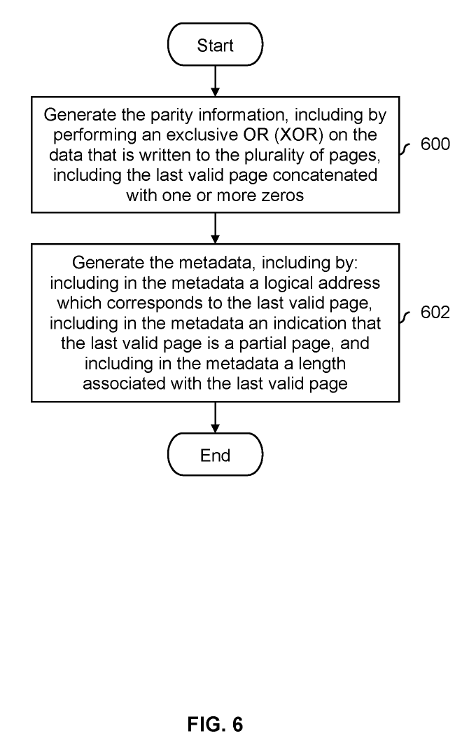

FIG. 6 is a flowchart illustrating an embodiment of a process to generate metadata and parity information for a partial page.

At 600, the parity information is generated, including by performing an exclusive OR (XOR) on the data that is written to the plurality of pages, including the last valid page concatenated with one or more zeros. See, for example, callout 410 in FIG. 4 where a zero fill is used to complete page x (which is a partial page) before page x is input to the XOR operation.

At 602, the metadata is generated, including by: including in the metadata a logical address which corresponds to the last valid page, including in the metadata an indication that the last valid page is a partial page, and including in the metadata a length associated with the last valid page. See, for example, partial page field 504 and length field 506 in FIG. 5. In some embodiments, step 602 is performed by keeping and/or managing a list of partial pages and lengths for those pages. In various embodiments, metadata is stored in a distributed manner (e.g., each piece of metadata is stored with or next to its corresponding host data) and/or centrally (e.g., in a list of partial pages and associated information).

As described above, once power is restored, the SSD system may perform a variety of processes. The following figures describe some examples of this.

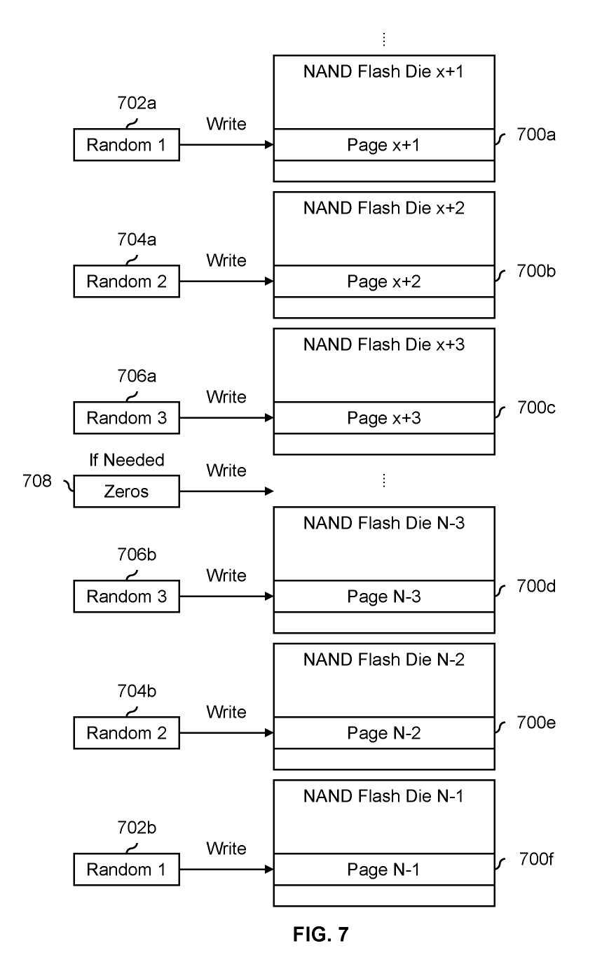

FIG. 7 is a diagram illustrating an embodiment of random sequences written to unwritten pages in a partial RAID group after power is restored. In the example shown, the unwritten pages from FIG. 2 and FIG. 4 are shown (i.e., page (x+1) through page (N−1)). If the unwritten pages are left in an unwritten state, then the system is vulnerable or otherwise susceptible to noise. To mitigate this, the unwritten pages are written which puts the system into a state which is less vulnerable or susceptible to noise.

Although a variety of sequences can be written to the unwritten pages to put them into a written state, random sequences are written in this example because random sequences impact other pages (e.g., pages adjacent to the page being written) the least. In this example, a first random sequence (702a and 702b) is written to page 700a as well as page 700f, a second random sequence (704a and 704b) is written to page 700b as well as page 700e, a third random sequence (706a and 706b) is written to page 700c as well as page 700d, and so on. In some embodiments, multiple random sequences are used (e.g., instead of using a single random sequence, reused over and over) because this is better for noise prevention.

The random sequences are written in pairs (i.e., a given random sequence is written to two different pages) because two instances of the same sequence cancel each other out in an XOR operation (e.g., which is used to generate RAID parity information). For example, (random 1) ⊕ (random 1) produces a sequence of zeros, as does (random 2) ⊕ (random 2) and (random 3) ⊕ (random 3). Since a sequence of zeros does not affect an XOR operation, writing random sequences in pairs will not change the already-stored RAID parity information (e.g., parity information 212 and 216 in FIG. 2 and parity information 410 in FIG. 4). Although this figure shows each random sequence only used twice, in some embodiments, a given random sequence is used four times, six times, etc.

If there are an odd number of unwritten pages, then a sequence of zeros (708) is written to one of the unwritten pages and the remaining (e.g., even) number of unwritten pages are written with pairs of random sequences. As described above, a sequence of zeros will not cause the RAID parity information to change and therefore can be used without affecting the RAID parity information if there is an odd number of unwritten pages.

By writing to the unwritten pages, the SSD is made less susceptible to noise. Also, by writing mostly or all random sequences, the already-written host data is minimally impacted since non-random sequences would adversely affect the already-written host data more than random sequences. Furthermore, by writing the random sequences in pairs (or, more generally, an even number of times) with an odd number of zero sequences (if needed), the already-stored parity information does not need to be updated and/or rewritten.

In this example, the writing shown here occurs after power is restored. By performing this writing after power is restored, the size of the backup battery can be smaller. If this writing were instead performed before power was restored, a larger backup battery would be required.

In addition to writing a neutral data pattern (i.e., some combination of data patterns or data sequences which (e.g., collectively) do not affect or are otherwise neutral with respect to some parity information), the system also validates the host data associated with the partial RAID group and rewrites it if necessary.

The following figure more formally describes the process shown here as a flowchart.

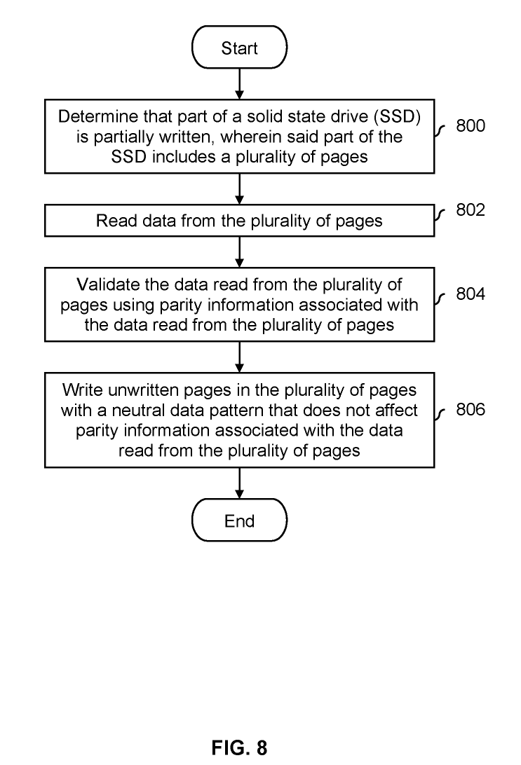

FIG. 8 is a flowchart illustrating an embodiment of a re-initialization process after power is restored. In some embodiments, the process of FIG. 8 is performed in combination with the process of FIG. 1 (e.g., FIG. 1 is performed before and after power is lost and FIG. 8 is performed once power is restored).

At 800, it is determined that part of a solid state drive (SSD) is partially written, wherein said part of the SSD includes a plurality of pages. For example, when power is restored, all of the metadata is re-read during a re-initialization process so that the state of the system is known. FIG. 5 shows an example of metadata which may be so ingested. If any metadata is encountered that has the “last valid page” field set to True or Yes (see, e.g., field 502 in FIG. 5), then the SSD knows that the current RAID group is a partial group and not a complete group. The “last valid page” field also permits the SSD to know where the last valid page is and therefore the subsequent or remaining pages are unwritten.

At 802, data is read from the plurality of pages. For example, in FIG. 2 and FIG. 4, host data from page 1 through page x would be read.

At 804, the data read from the plurality of pages is validated using parity information associated with the data read from the plurality of pages. For example, using the host data from page 1 through page x, parity information is regenerated by XORing page 1 through page x. If the regenerated parity information matches some previously stored or recorded information (e.g., stored at step 104 in FIG. 1 if FIG. 1 and FIG. 8 are performed together), then the data read from the plurality of pages is (e.g., successfully) validated.

Although not shown here, if the two versions of parity information do not match, then it is assumed that one of the pages in the partial RAID group (e.g., read at step 802) has been corrupted. Using the stored parity information, recovered data is generated for the bad data, and the recovered data is written to the appropriate page.

At 806, unwritten pages in the plurality of pages are written with a neutral data pattern that does not affect a parity information associated with the data read from the plurality of pages. The neutral data pattern can be generated using, for example, by writing an even number of random sequences and an odd number of zero sequences if the latter is needed (e.g., if there are an odd number of unwritten pages); one example is shown in FIG. 7.

The following figure shows a more detailed example of step 806.

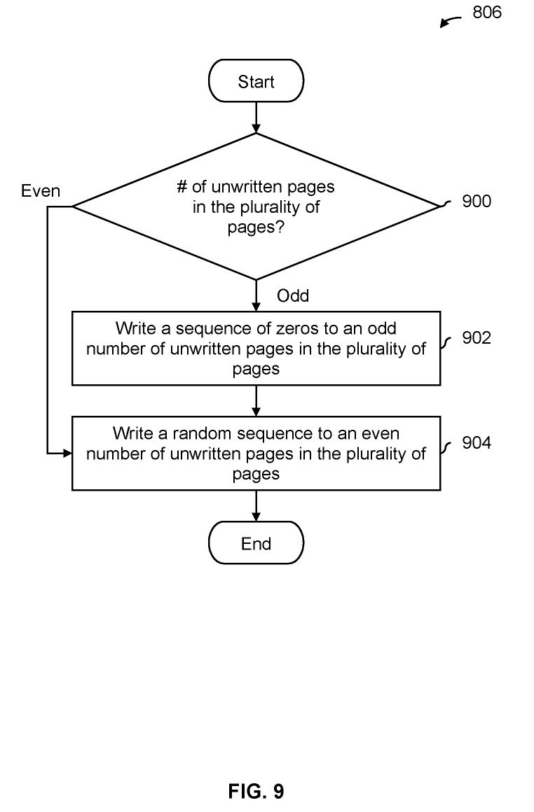

FIG. 9 is a flowchart illustrating an embodiment of a process to write a neutral data pattern. In some embodiments, step 806 in FIG. 8 includes the process of FIG. 9.

At 900, the number of unwritten pages in the plurality of pages is determined. If there is an odd number of pages, a sequence of zeros is written to an odd number of unwritten pages in the plurality of pages at 902. In some embodiments, the sequence of zeros is written once. After writing at 902, an even number of unwritten pages remains.

After writing the sequence of zeros at 902 or if there is an even number of unwritten pages at step 900, then at 904, a random sequence is written to an even number of unwritten pages in the plurality of pages. In the example of FIG. 7, a given random sequence is written two times (e.g., to two different unwritten pages) and multiple random sequences are used.

The following figures describe an example in which metadata associated with a partial RAID group is modified (e.g., once power is restored) so that it matches metadata for a complete RAID group.

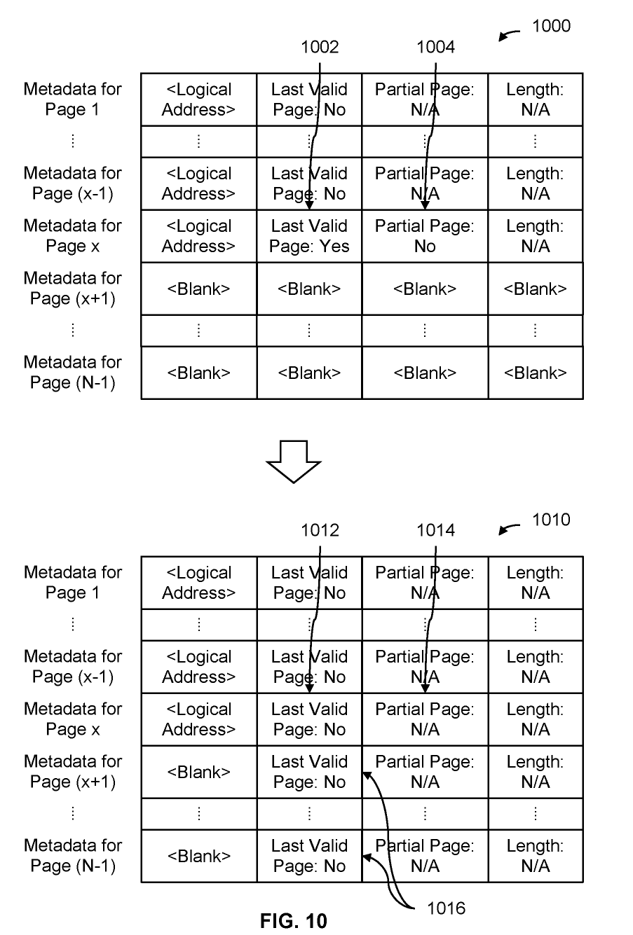

FIG. 10 is a diagram illustrating an embodiment of metadata associated with a partial RAID group before and after being updated once power is restored. In the example shown, diagram 1000 shows metadata associated with the partial RAID group shown in FIG. 2. Note, for example, that field 1002 indicates that page x is the last valid page for this RAID group and field 1004 indicates that page x is a complete page (e.g., so there is no zero fill at the end of page x). The metadata for page (x+1) through page (N−1) is blank because power was lost before host data could be written to those pages.

As part of the processing that is performed after power is restored, the metadata associated with the partial RAID group is updated so that it resembles (e.g., as much as possible) metadata associated with a complete RAID group (e.g., where there is no unexpected loss of power while writing host data). See, for example, diagram 1010 where the metadata has been modified to match that of a complete RAID group. Note, for example, that field 1012 has been updated so that the last valid page field is set to No for page x and field 1014 is now no longer applicable (e.g., because field 1012 is set to No). The last valid page fields for the unwritten pages (1016) have also been updated to be set to No (e.g., because for metadata corresponding to a complete RAID group, all “last valid page” fields are set to No).

A complete RAID group is the more common scenario (e.g., because a partial RAID group arises only when there is an unexpected loss of power or due to some other unusual situation) and in some applications it is desirable to have the metadata conform as much as possible. Updating the metadata in the manner shown may also consume less storage since less storage needs to be used to record information associated with exceptions or partial RAID groups.

In this example, it is assumed that the SSD does not need to record where exactly the host data ends and so the metadata is able to be updated in this manner once power is restored. In implementations where the SSD needs to remember some of the information which is erased here (e.g., because the host will not remember and the SSD needs to keep track of the end of the host data so as not to return a random sequence or a sequence of zeros), the metadata is made to match metadata for a complete RAID group (i.e., which is the more common configuration) to the degree possible.

The following figure more formally describes the process shown here as a flowchart.

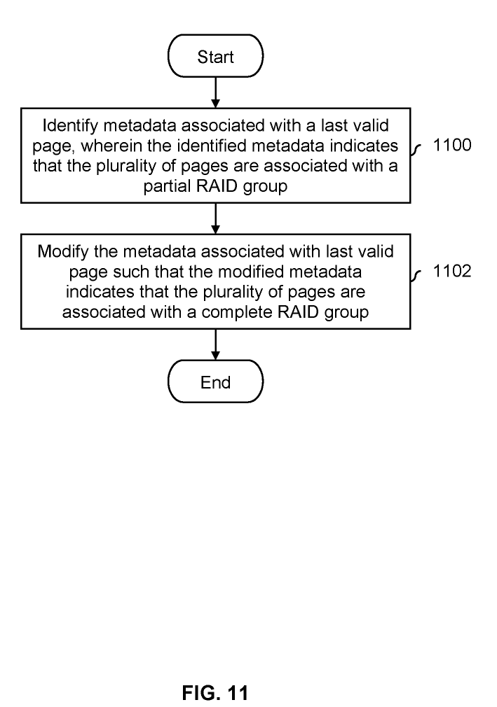

FIG. 11 is a flowchart illustrating an embodiment of a process to modify metadata associated with a partial RAID group so that it resembles metadata for a complete RAID group once power is restored. In some embodiments, the process of FIG. 11 is performed in combination with the process of FIG. 8.

At 1100, metadata associated with a last valid page is identified, wherein the identified metadata indicates that the plurality of pages are associated with a partial RAID group. For example, step 1100 may be part of a re-initialization process where all of the metadata in the SSD is ingested so that the state of the SSD is known. Using FIG. 10 as an example, field 1002 is set to Yes and shows an example of metadata identified at step 1100.

At 1102, the metadata associated with the last valid page is modified such that the modified metadata indicates that the plurality of pages are associated with a complete RAID group. See, for example, diagram 1010 in FIG. 10.

Although the foregoing embodiments have been described in some detail for purposes of clarity of understanding, the invention is not limited to the details provided. There are many alternative ways of implementing the invention. The disclosed embodiments are illustrative and not restrictive.

What is claimed is:

1. A system for providing parity protection to a solid state drive, comprising:
the solid state drive, including a plurality of pages; and
a NAND Flash controller configured to:
initiate data writing to the plurality of pages included in the solid state drive;
detect a power loss while there is at least one page amongst the plurality of pages that is at least partially unwritten; and
provide parity protection for the plurality of pages, including by: recording parity information based at least in part on data that is written to the plurality of pages and recording metadata associated with a last valid page.

2. The system recited in claim 1, wherein the metadata associated with the last valid page is recorded in a header associated with the last valid page.

3. The system recited in claim 1, wherein the metadata associated with the last valid page is recorded in a central location.

4. The system recited in claim 1, wherein the NAND Flash controller is further configured to:
generate the parity information, including by performing an exclusive OR (XOR) on the data that is written to the plurality of pages, including the last valid page; and
generate the metadata, including by including in the metadata a logical address which corresponds to the last valid page.

5. The system recited in claim 1, wherein the NAND Flash controller is further configured to:
generate the parity information, including by performing an exclusive OR (XOR) on the data that is written to the plurality of pages, including the last valid page concatenated with one or more zeros; and
generate the metadata, including by: (1) including in the metadata a logical address which corresponds to the last valid page, (2) including in the metadata an indication that the last valid page is a partial page, and (3) including in the metadata a length associated with the last valid page.

6. The system recited in claim 1, wherein the NAND Flash controller is further configured to:
read data from the plurality of pages;
validate the data read from the plurality of pages using the parity information; and
write unwritten pages in the plurality of pages with a neutral data pattern that does not affect the parity information.

7. The system recited in claim 1, wherein the NAND Flash controller is further configured to:
read data from the plurality of pages;
validate the data read from the plurality of pages using the parity information; and
write unwritten pages in the plurality of pages with a neutral data pattern that does not affect the parity information, including by:
determining a number of unwritten pages in the plurality of pages;
in the event it is determined that there is an odd number of unwritten pages:
writing a sequence of zeros to the odd number of unwritten pages in the plurality of pages; and
writing a random sequence to an even number of unwritten pages in the plurality of pages; and
in the event it is determined that there is an even number of unwritten pages, writing the random sequence to the even number of unwritten pages in the plurality of pages.

8. The system recited in claim 1, wherein the NAND Flash controller is further configured to:
read data from the plurality of pages;
validate the data read from the plurality of pages using the parity information;
write unwritten pages in the plurality of pages with a neutral data pattern that does not affect the parity information;
identify the metadata associated with the last valid page, wherein the identified metadata indicates that the plurality of pages are associated with a partial RAID group; and
modify the metadata associated with the last valid page such that the modified metadata indicates that the plurality of pages are associated with a complete RAID group.

9. A method of providing parity protection to a solid state drive, comprising:
initiating data writing to a plurality of pages included in the solid state drive;
detecting a power loss while there is at least one page amongst the plurality of pages that is at least partially unwritten; and
providing parity protection for the plurality of pages, including by: recording parity information based at least in part on data that is written to the plurality of pages and recording metadata associated with a last valid page.

10. The method recited in claim 9, wherein the metadata associated with the last valid page is recorded in a header associated with the last valid page.

11. The method recited in claim 9, wherein the metadata associated with the last valid page is recorded in a central location.

12. The method recited in claim 9 further comprising:
generating the parity information, including by performing an exclusive OR (XOR) on the data that is written to the plurality of pages, including the last valid page; and
generating the metadata, including by including in the metadata a logical address which corresponds to the last valid page.

13. The method recited in claim 9 further comprising:
generating the parity information, including by performing an exclusive OR (XOR) on the data that is written to the plurality of pages, including the last valid page concatenated with one or more zeros; and
generating the metadata, including by: (1) including in the metadata a logical address which corresponds to the last valid page, (2) including in the metadata an indication that the last valid page is a partial page, and (3) including in the metadata a length associated with the last valid page.

14. The method recited in claim 9 further comprising:
reading data from the plurality of pages;
validating the data read from the plurality of pages using the parity information; and
writing unwritten pages in the plurality of pages with a neutral data pattern that does not affect the parity information.

15. The method recited in claim 9 further comprising:
reading data from the plurality of pages;
validating the data read from the plurality of pages using the parity information; and
writing unwritten pages in the plurality of pages with a neutral data pattern that does not affect the parity information, including by:
determining a number of unwritten pages in the plurality of pages;
in the event it is determined that there is an odd number of unwritten pages:
writing a sequence of zeros to the odd number of unwritten pages in the plurality of pages; and
writing a random sequence to an even number of unwritten pages in the plurality of pages; and
in the event it is determined that there is an even number of unwritten pages, writing the random sequence to the even number of unwritten pages in the plurality of pages.

16. The method recited in claim 9 further comprising:
reading data from the plurality of pages;
validating the data read from the plurality of pages using the parity information;
writing unwritten pages in the plurality of pages with a neutral data pattern that does not affect the parity information;
identifying the metadata associated with the last valid page, wherein the identified metadata indicates that the plurality of pages are associated with a partial RAID group; and
modifying the metadata associated with the last valid page such that the modified metadata indicates that the plurality of pages are associated with a complete RAID group.

17. A system for reinitializing a solid state drive, including:
the solid state drive; and
a NAND Flash controller configured to:
determine that part of the solid state drive is partially written, wherein said part of the solid state drive includes a plurality of pages;
read data from the plurality of pages;
validate the data read from the plurality of pages using parity information associated with the data read from the plurality of pages; and
write unwritten pages in the plurality of pages with a neutral data pattern that does not affect the parity information associated with the data read from the plurality of pages.

18. The system recited in claim 17, wherein writing unwritten pages includes:
determining a number of unwritten pages in the plurality of pages;
in the event it is determined that there is an odd number of unwritten pages:
writing a sequence of zeros to the odd number of unwritten pages in the plurality of pages; and
writing a random sequence to an even number of unwritten pages in the plurality of pages; and
in the event it is determined that there is an even number of unwritten pages, writing the random sequence to the even number of unwritten pages in the plurality of pages.

19. The system recited in claim 17, wherein the NAND Flash controller is further configured to:
identify metadata associated with a last valid page, wherein the identified metadata indicates that the plurality of pages are associated with a partial RAID group; and
modify the metadata associated with the last valid page such that the modified metadata indicates that the plurality of pages are associated with a complete RAID group.
